(19) United States
(12) Patent Application Publication
(10) Pub. No.: US 2024/0145467 A1
(43) Pub. Date: May 2, 2024

(54) SEMICONDUCTOR DEVICE, METHOD OF MANUFACTURING SEMICONDUCTOR DEVICE, AND METHOD OF REPLACING SEMICONDUCTOR DEVICE

(71) Applicant: MITSUBISHI ELECTRIC CORPORATION, Tokyo (JP)

(72) Inventor: Toshiaki IWAMATSU, Tokyo (JP)

(73) Assignee: Mitsubishi Electric Corporation, Tokyo (JP)

(21) Appl. No.: 18/279,067

(22) PCT Filed: Mar. 29, 2021
(86) PCT No.: PCT/JP2021/013293

§ 371 Date: Aug. 28, 2023

(51) Int. Cl. H01L 27/088; H01L 29/423; H01L 29/66; H01L 29/78

(52) U.S. Cl. CPC H01L 27/088; H01L 29/42364; H01L 29/66681; H01L 29/66712; H01L 29/7803; H01L 29/7817

(57) ABSTRACT

An object is to provide a technology capable of predicting fluctuation in electrical characteristics of vertical semiconductor transistors when operated in the market. The semiconductor device includes a vertical semiconductor transistor and a horizontal semiconductor transistor provided on the same semiconductor base. A gate electrode of the vertical semiconductor transistor and a gate electrode of the horizontal semiconductor transistor are electrically connected. A source electrode of the vertical semiconductor transistor and a source electrode of the horizontal semiconductor transistor are electrically connected.

### TECHNICAL FIELD

The present disclosure relates to a semiconductor device, a method of manufacturing the semiconductor device, and a method of replacing the semiconductor device.

### BACKGROUND ART

MOS gate semiconductor devices are widely used as semiconductor devices for power control. A MOS gate semiconductor device is a semiconductor device having a gate electrode of a MOS structure such as a Metal Oxide Semiconductor Field Effect Transistor (MOSFET), an Insulated Gate Bipolar Transistor (IGBT). The MOS gate semiconductor device is provided on a semiconductor substrate or the like as a semiconductor chip, also called an element.

Even if the semiconductor chips are obtained from the same semiconductor wafer, the electrical characteristics of every element differ due to manufacturing variations. For this reason, there has been a problem in that, in a circuit in which a plurality of elements are used in parallel, such as a three-phase bridge circuit, its variations in electrical characteristics become greater than that in a single element. In order to solve the problem of each element having different electrical characteristics, Patent Document 1 proposes a technique of selecting elements having similar electrical characteristics and assembling them on a circuit board.

### PRIOR ART DOCUMENTS

### Patent Document(s)

[Patent Document 1] Japanese Patent Application Laid-Open No. 2010-199362

### SUMMARY

### Problem to be Solved by the Invention

However, the electrical characteristics of a circuit inevitably change over time due to device operation in the market (also referred to as device operation in actual use). For this reason, even if elements with similar electrical characteristics are selected during element selection in the assembly process, the difference in change over time in the electrical characteristics of each element may become larger during operation of the elements in the market in some cases. As a result, there has been a problem that circuit operation during operation in the market may become unstable.

Therefore, the present disclosure has been made in view of the aforementioned problem, and an object thereof is to provide a technology capable of predicting fluctuation in electrical characteristics of vertical semiconductor transistors when operated in the market.

### Means to Solve the Problem

A semiconductor device according to the present disclosure includes a vertical semiconductor transistor and a horizontal semiconductor transistor provided on a same semiconductor base, in which a gate electrode of the vertical semiconductor transistor and a gate electrode of the horizontal semiconductor transistor are electrically connected, a source electrode of the vertical semiconductor transistor and a source electrode of the horizontal semiconductor transistor are electrically connected, a drain electrode of the vertical semiconductor transistor and a drain electrode of the horizontal semiconductor transistor are provided on opposite sides with respect to the semiconductor base, and a threshold voltage of the horizontal semiconductor transistor is higher than a threshold voltage of the vertical semiconductor transistor.

### Effects of the Invention

According to the present disclosure, the vertical semiconductor transistor and the horizontal semiconductor transistor are provided on the same semiconductor base; therefore, the electrical characteristics of the vertical semiconductor transistor can be predicted by obtaining the electrical characteristics of the horizontal semiconductor transistor.

The objects, features, aspects, and advantages of the present disclosure will become more apparent from the following detailed description and the accompanying drawings.

### BRIEF DESCRIPTION OF DRAWINGS

FIG. 1 A plan view illustrating a configuration of a semiconductor device according to Embodiment 1.

FIG. 2 A cross-sectional view illustrating the configuration of the semiconductor device according to Embodiment 1.

FIG. 3 A cross-sectional view illustrating another configuration of a semiconductor device according to Embodiment 1.

FIG. 4 A cross-sectional view illustrating a method of manufacturing the semiconductor device according to Embodiment 1.

FIG. 5 A cross-sectional view illustrating the method of manufacturing the semiconductor device according to Embodiment 1.

FIG. 6 A cross-sectional view illustrating the method of manufacturing the semiconductor device according to Embodiment 1.

FIG. 7 A flowchart illustrating a method of manufacturing a power module according to Embodiment 1.

FIG. 8 A plan view illustrating the configuration of the semiconductor device according to Embodiment 1.

FIG. 9 A plan view illustrating another configuration of the semiconductor device according to Embodiment 1.

FIG. 10 A graph illustrating measurement results of the threshold voltage of the semiconductor device according to Embodiment 1.

FIG. 11 A circuit diagram illustrating an example of a half bridge circuit.

FIG. 12 A circuit diagram illustrating an example of a half bridge circuit.

FIG. 13 A cross-sectional view illustrating a configuration of a semiconductor device according to Embodiment 2.

FIG. 14 A cross-sectional view illustrating a method of manufacturing the semiconductor device according to Embodiment 2.

FIG. 15 A cross-sectional view illustrating a method of manufacturing the semiconductor device according to Embodiment 2.

FIG. 16 A cross-sectional view illustrating a method of manufacturing the semiconductor device according to Embodiment 2.

FIG. 17 A cross-sectional view illustrating a method of manufacturing the semiconductor device according to Embodiment 2.

### DESCRIPTION OF EMBODIMENT(S)

Hereinafter, Embodiments will be described with reference to the attached drawings. Features described in each of following Embodiments are examples; therefore, not all features are necessarily essential. Further, in the description to be made below, similar components are denoted by the same or similar reference numerals across a plurality of Embodiments, and descriptions of different components will be mainly made.

Also in the description described below, when terms specifying specific positions and directions such as “up”, “low”, “side”, “front”, “back” and the like are used for promoting the understanding of the contents of Embodiments; therefore, they do not necessarily coincide with the positions and directions at the time of implementation. Also, an impurity concentration indicates a peak value of the impurity concentration in each region. In the following, although it is described that n-type represents the first conductive type and p-type represents the second conductive type, p-type may represent the first conductive type and n-type may represent the second conductive type.

### Embodiment 1

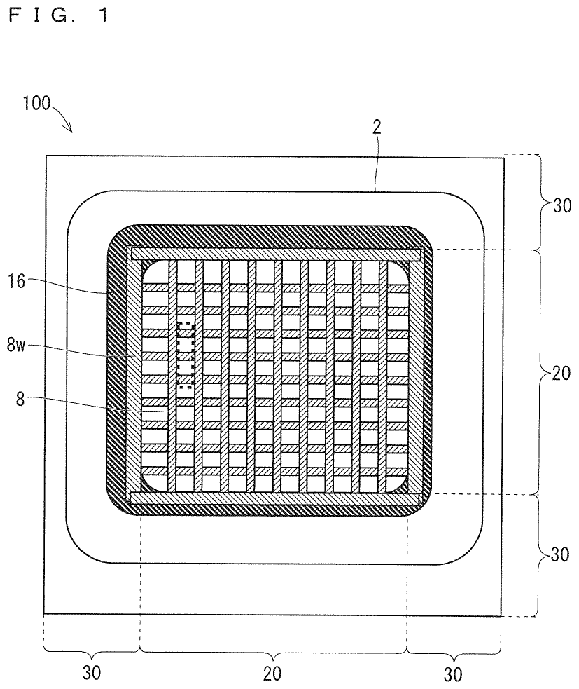

FIG. 1 is a plan view illustrating a configuration of a semiconductor device 100 according to Embodiment 1. In FIG. 1, the semiconductor device 100 is a semiconductor chip including an active region 20 provided in the central portion of the semiconductor device 100 and a termination region 30 provided in the outer peripheral portion of the semiconductor device 100 in plan view. The outer peripheral portion is a portion located outside the semiconductor device 100 rather than the inside of the semiconductor device 100 in plan view of the semiconductor device 100 illustrated in FIG. 1, and the central portion is the portion located in the opposite direction to the outer peripheral portion.

The active region 20 is a region through which a current flows when a channel is formed in the ON state of the semiconductor device 100. The termination region 30 is provided around the active region 20 and serves as a region that insulates the active region 20 from the outside.

In FIG. 1, gate electrodes 8 are provided in a grid pattern. A plurality of cells are provided in regions partitioned by the gate electrodes 8 in the active region 20. The cells may be arranged in a houndstooth pattern instead of the grid pattern illustrated in FIG. 1. Further, the shape of each gate electrode 8 may be a stripe shape that extends only in one direction of the semiconductor device 100 in plan view, and the shape of each cell may also be stripe-shaped.

The gate electrode 8 includes gate wiring 8w provided on the outer periphery portion of a semiconductor layer 2. A field oxide film 16 is provided as an underlayer of the gate wiring 8w. Although not illustrated, a gate contact is provided on the protective layer on the gate wiring 8w, and the gate wiring 8w is electrically connected to a gate pad via the gate contact. The field oxide film 16 being an underlayer of the gate wiring 8w is thicker than a gate oxide film of a MOSFET in the cell; therefore, even when the gate voltage is applied to the gate wiring 8w, the breakage of the field oxide film 16 is suppressed. Further, the field oxide film 16 is thicker than the gate oxide film; therefore, the capacitance of the oxide film between the gate wiring 8w and the semiconductor layer 2 being an underlayer of the field oxide film 16 is also relatively small.

<Cross-Sectional Configuration>

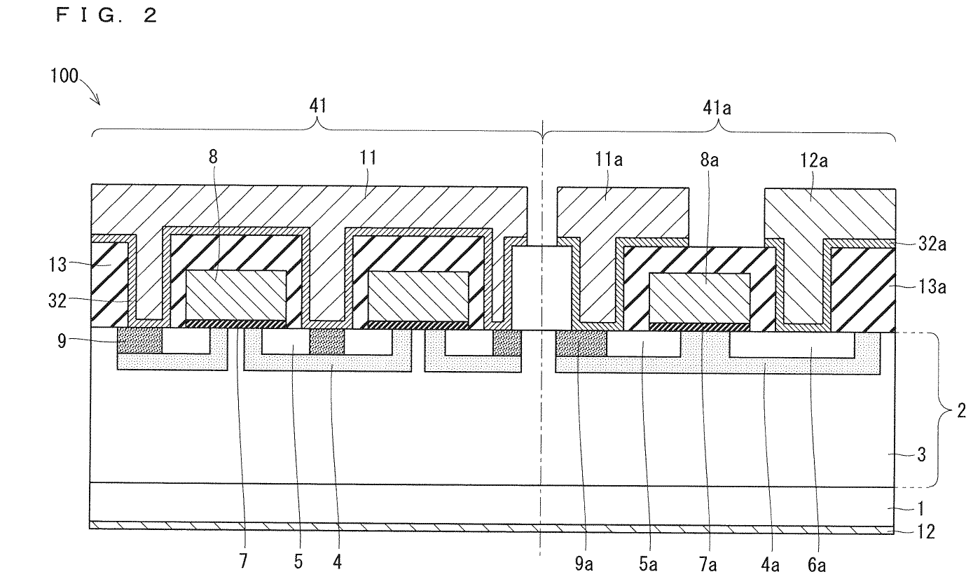

FIG. 2 is a cross-sectional view illustrating the configuration of a portion indicated by the dashed line in FIG. 1. The semiconductor device 100 includes a vertical semiconductor transistor and a horizontal semiconductor transistor provided on the same semiconductor base.

In Embodiment 1, although the semiconductor base includes an n-type semiconductor substrate 1 and an n-type semiconductor layer 2, the configuration thereof is not limited thereto. For example, the semiconductor base may include any one of the semiconductor substrate 1 and the semiconductor layer 2. Also in the following, a configuration in which at least part of the semiconductor base, such as a drift layer 3, contains silicon carbide (SiC) will be described, however, the configuration may also include a wide bandgap semiconductor such as gallium nitride (GaN) and diamond, which has a larger bandgap than silicon.

In Embodiment 1, the vertical semiconductor transistor represents the n-channel high voltage MOSFET 41, and the horizontal semiconductor transistor represents the n-channel monitor MOSFET 41a, however, the configuration is not limited thereto. For example, the vertical semiconductor transistor may represent a p-channel high voltage MOSFET, an IGBT, or a trench gate semiconductor transistor.

As described above, the high voltage MOSFET 41 and the monitor MOSFET 41a are provided on the same semiconductor substrate 1 and the same semiconductor layer 2 in Embodiment 1. The high voltage MOSFET 41 in the example of FIG. 2 includes a drift layer 3, a well region 4, a source region 5, a gate insulating film 7, a gate electrode 8, a well contact region 9, a source electrode 11, a drain electrode 12, and an interlayer insulating film 13. The monitor MOSFET 41a in the example of FIG. 2 includes the drift layer 3, a well region 4a, a source region 5a, a drain region 6a, a gate insulating film 7a, a gate electrode 8a, a well contact region 9a, a source electrode 11a, a drain electrode 12a, and an interlayer insulating film 13a.

The semiconductor layer 2 is provided on the semiconductor substrate 1, and includes the n-type drift layer 3, p-type well regions 4 and 4a, n-type source regions 5 and 5a, an n-type drain region 6a, and p-type well contact regions 9 and 9a.

The drift layer 3 is a portion of the semiconductor layer 2 on the semiconductor substrate 1 side. The well regions 4 and 4a are selectively provided on the drift layer 3. The source region 5 and the well contact region 9 adjacent to each other are selectively provided on the well region 4. The source region 5a and the well contact region 9a adjacent to each other and the drain region 6a separated therefrom are selectively provided on the well region 4a. The well contact region 9 equalizes the potentials of the source region 5 and the well region 4, this enables to suppress the operation of the parasitic transistor. Similarly, the well contact region 9a equalizes the potentials of the source region 5a and the well region 4a, this enables to suppress the operation of the parasitic transistor.

The gate electrode 8 is provided on the source region 5 and on the well regions 4 and the drift layer 3 interposed between the source regions 5 through an insulating gate insulating film 7. An interlayer insulating film 13 separating the gate electrode 8 and the source electrode 11 is provided on the gate electrode 8. A contact hole is provided in the interlayer insulating film 13 to expose the source region 5 and the well contact region 9. The source electrode 11 in contact with the source region 5 and the well contact region 9 through a barrier metal 32 is provided on the interlayer insulating film 13 through the barrier metal 32. The drain electrode 12 is provided on the lower part of the semiconductor substrate 1.

A gate electrode 8a is provided on the source region 5a and the drain region 6a and on the well region 4a interposed therebetween through an insulating gate insulating film 7a. An interlayer insulating film 13a separating the gate electrode 8a and the source electrode 11a is provided on the gate electrode 8a. The interlayer insulating film 13a is provided with a contact hole to expose the source region 5a and the well contact region 9a and a contact hole to expose the drain region 6a. The source electrode 11a in contact with the source region 5a and the well contact region 9a through a barrier metal 32a is provided on the interlayer insulating film 13a through the barrier metal 32a. The drain electrode 12a in contact with the drain region 6a through the barrier metal 32a is provided on the interlayer insulating film 13a through the barrier metal 32a.

In Embodiment 1, the drain electrode 12 of the high voltage MOSFET 41 and the drain electrode 12a of the monitor MOSFET 41a are provided on opposite sides with respect to the semiconductor base. In FIG. 2, the drain electrode 12 is provided below the semiconductor substrate 1 and the semiconductor layer 2, and the drain electrode 12a is provided above the semiconductor substrate 1 and the semiconductor layer 2, as an example.

Further, as will be described later, in Embodiment 1, the gate electrode 8 of the high voltage MOSFET 41 and the gate electrode 8a of the monitor MOSFET 41a are electrically connected. The gate insulating film 7 of the high voltage MOSFET 41 and the gate insulating film 7a of the monitor MOSFET 41a have the same material and the same thickness, the threshold voltage of the monitor MOSFET 41a is the same as the threshold voltage of the high voltage MOSFET 41 until a high gate voltage is applied to the monitor MOSFET 41a, which will be described later. Here, that the gate insulating film 7 and the gate insulating film 7a have the same thickness means that the difference between the gate insulating film 7 and the gate insulating film 7a is i3% or less of the total thickness.

Note that the monitor MOSFET 41a is provided in an active region 20 illustrated in FIG. 1, as is the same with the high voltage MOSFET 41. The region where the monitor MOSFET 41a is provided may be provided in any region within the active region 20, the area of the monitor MOSFET 41a may be the minimum area, and the minimum area may be about the same as the area where two to three high voltage MOSFET 41 cells are arranged.

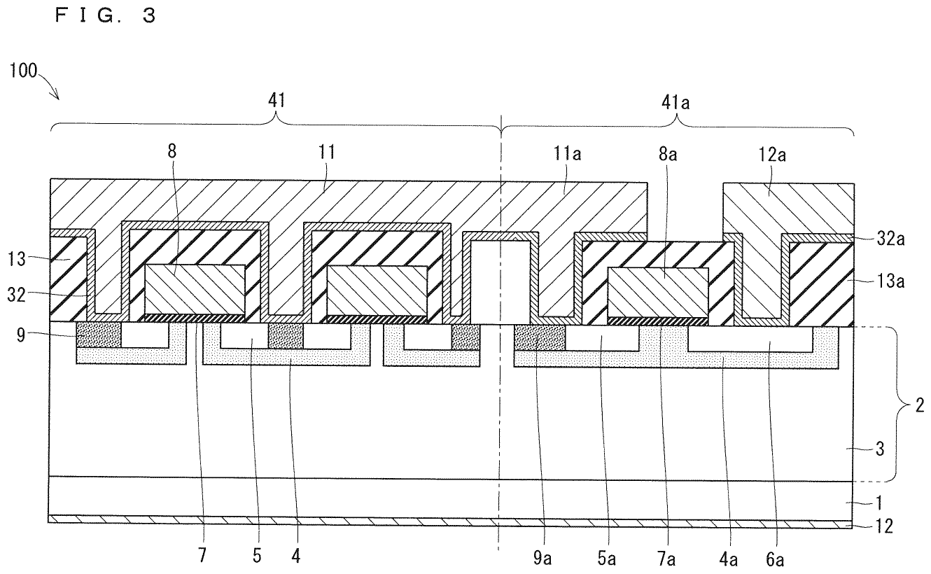

FIG. 3 is a cross-sectional view illustrating another configuration of a portion indicated by the dashed line in FIG. 1. As illustrated in FIG. 3, in the configuration of FIG. 2, the source electrode 11 of the high voltage MOSFET 41 and the source electrode 11a of the monitor MOSFET 41a may be electrically connected by being in direct contact with each other. In the configuration, one pad may be provided for the entire source electrode 11 and source electrode 11a.

<Operation of Semiconductor Device>

Next, the operation of a semiconductor device 100 according to Embodiment 1 will be described.

First, the operation of the high voltage MOSFET 41 will be described. When a positive voltage is applied to the gate electrode 8, a channel is formed in the well region 4 at a portion that is in contact with the gate insulating film 7, which serves as a current path. When a positive voltage is applied to drain electrode 12 in this state, a current flows from the drain electrode 12 to the source electrode 11 via the semiconductor substrate 1, the drift layer 3, the well region 4, and the source region 5. Meanwhile, when the application of the positive voltage to the gate electrode 8 is canceled or the negative voltage is applied to the gate electrode 8, depletion occurs in the well region 4 in the portion that is in contact with the gate insulating film 7. Therefore, even when a high voltage is applied to the drain electrode 12, current flow between the drain and the source is interrupted.

Next, the operation of the monitor MOSFET 41a will be described. When a positive voltage is applied to the gate electrode 8a, a channel is formed in the well region 4a at a portion that is in contact with the gate insulating film 7a, which serves as a current path. When a positive voltage is applied to drain electrode 12a in this state, a current flows from the drain electrode 12a to the source electrode 11a via the drain region 6a, the well region 4a, and the source region 5a. Meanwhile, when the application of the positive voltage to the gate electrode 8a is canceled or the negative voltage is applied to the gate electrode 8a, depletion occurs in the well region 4a in the portion that is in contact with the gate insulating film 7a. Therefore, even when a high voltage is applied to the drain electrode 12a, current flow between the drain and the source is interrupted.

In both MOSFETs, as the positive voltage applied to the gate electrodes 8 and 8a is increased, the current flow between the drain and the source increases. For example, when the drain voltage is 10 V and the source voltage is 0 V, the gate voltage when the drain-source current flowing through the MOSFET reaches the standard value is set as the threshold voltage.

<Method of Manufacturing Semiconductor Device>

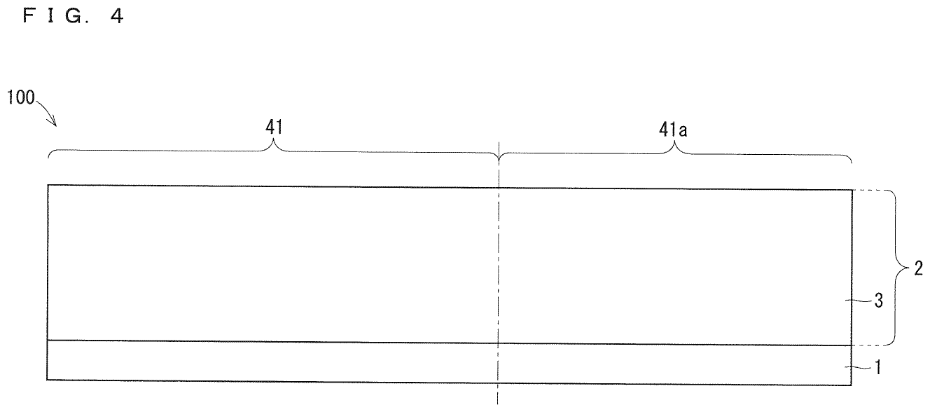

Next, a method of manufacturing the semiconductor device according to Embodiment 1 will be described with reference to FIGS. 4 to 6.

As illustrated in FIG. 4, an n-type low-resistance semiconductor substrate 1 is prepared, and a semiconductor layer 2 including an n-type drift layer 3 is formed on the semiconductor substrate 1 by epitaxial growth. The semiconductor substrate 1 in the example of FIG. 4 is a portion of a semiconductor wafer, and the semiconductor wafer extends in the in-plane direction of the semiconductor substrate 1 in FIG. 4. The n-type impurity concentration of the drift layer 3 is, for example, about 1×10¹³ cm⁻³ to 1×10¹⁸ cm⁻³ and the thickness thereof is, for example, 4 μm to 200 m.

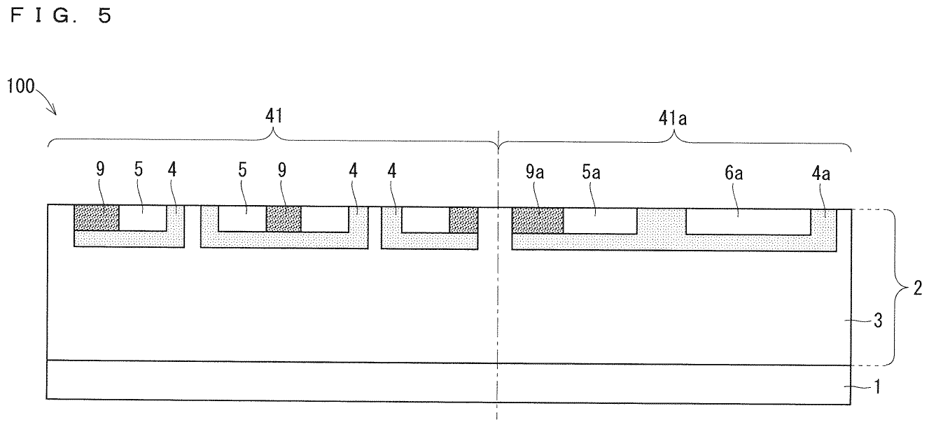

As illustrated in FIG. 5, the p-type well regions 4 and 4a which are apart from each other are selectively formed on drift layer 3. In addition, an n-type source region 5 and a p-type well contact region 9 adjacent to each other are selectively formed on the well region 4, and an n-type source region 5a and a p-type well contact region 9a adjacent to each other and an n-type drain region 6a separated therefrom are selectively formed on the well region 4a. For example, the p-type region is formed by implanting Al ions and the n-type region is formed by implanting N ions using, a resist, an oxide film or the like processed by photolithography as a mask.

The p-type impurity concentration of the well region 4 is, for example, about 1×10¹⁵ cm⁻³ to 1×10¹⁸ cm⁻³ and the well region 4 is formed to have a depth of, for example, 0.3 μm to 2.0 μm from the upper surface of the semiconductor substrate 1. The n-type impurity concentration of the source region 5 is, for example, about 1×10¹⁷ cm⁻³ to 1×10²¹ cm⁻³, which is higher than that of the well region 4, and the bottom surface of the source region 5 is formed so as not to be located below the bottom surface of the well region 4. The well contact region 9 is formed to have the impurity concentration higher than that of well region 4.

Next, annealing is performed in an inert gas atmosphere such as argon gas using a heat treatment apparatus. Annealing is performed, for example, at a temperature of 1300° C. to 1900° C. for about 30 seconds to 1 hour. This annealing activates the ion-implanted n-type impurities such as N and the p-type impurities such as Al.

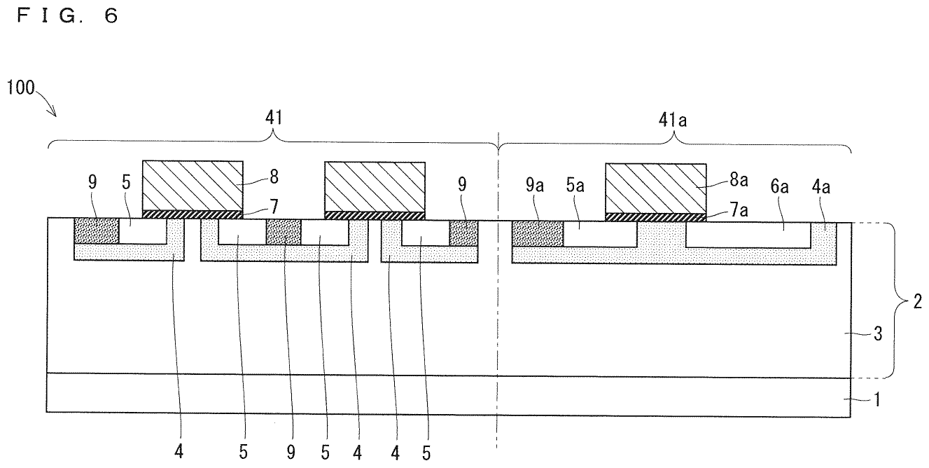

Next, as illustrated in FIG. 6, gate insulating films 7 and 7a are formed. The gate insulating films 7 and 7a are formed by dry thermal oxidation at 1150° C. or higher, for example. The gate insulating films 7 and 7a may be formed by a deposition method. Heat treatment may be performed in a nitrogen or ammonia atmosphere after the gate insulating films 7 and 7a are formed. Further, the front surface of the drift layer 3 may be annealed at a high temperature in a hydrogen atmosphere before the gate insulating films 7 and 7a are formed.

Then, gate electrodes 8 and 8a are formed. For example, the gate electrodes 8 and 8a are formed by depositing polysilicon by a Chemical Vapor Deposition (CVD) method and performing etching using a resist processed by photolithography as a mask. Polysilicon may contain impurities such as phosphorus (P) and boron (B). By containing impurities in polysilicon, the sheet resistance of the gate electrodes 8 and 8a can be reduced.

Finally, interlayer insulating films 13 and 13a having contact holes are formed, and then source electrodes 11 and 11a and drain electrodes 12 and 12a are formed, thereby completing the high voltage MOSFET 41 and the monitor MOSFET 41a illustrated in FIG. 2 (or in FIG. 3).

The wiring used to extract the gate electrodes 8 and 8a and the source electrodes 11 and 11a are formed by depositing metal films of Al, Cu, Ti, Ni, Mo, W, and Ta, nitride metal films of the same, laminated films of the same, or alloy layers of the same by sputtering or vapor deposition methods, and then patterning is performed thereon. The drain electrode 12 is formed, for example, by depositing a metal film of Ti, Ni, Ag, Au, or the like by a sputtering method, a vapor deposition method, or the like, and then patterning is performed thereon.

In Embodiment 1, the well region 4a, the gate insulating film 7a and the gate electrode 8a are formed in the same Steps as the well region 4, the gate insulating film 7 and the gate electrode 8a, respectively. Accordingly, the materials of the corresponding constituent elements are the same, and the shapes including the thicknesses of the corresponding constituent elements are the same. Therefore, the threshold voltage of the monitor MOSFET 41a is the same as the threshold voltage of the high voltage MOSFET 41.

<Method of Manufacturing Module>

After completing the formation of MOSFETs on the semiconductor substrate 1, a module is formed. First, the outline of the formation of the module will be described. After the MOSFETs are formed on a semiconductor wafer, the electrical characteristics of the monitor MOSFETs 41a are measured and obtained in order to determine the quality of the elements. Then, the semiconductor wafer is cut (diced) into individual elements (also called semiconductor chips). Then, non-defective elements are selected based on the electrical characteristics, and a power module is assembled from a plurality of selected elements. A non-defective element is a semiconductor device whose electrical characteristics obtained from the monitor MOSFET 41a satisfy a predetermined standard.

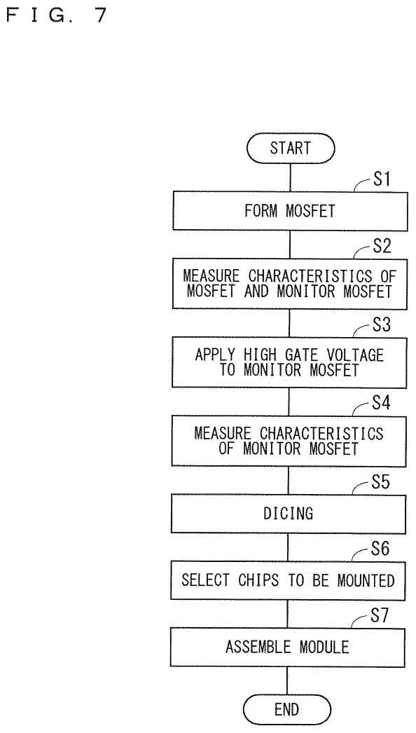

FIG. 7 is a flowchart illustrating a method of manufacturing a power module according to Embodiment 1.

First, in Step S1, the high voltage MOSFET 41 and the monitor MOSFET 41a are formed on the semiconductor substrate 1 by performing the above-described method of manufacturing the semiconductor device up until before cutting the semiconductor wafer.

In Step S2, electrical characteristics of the high voltage MOSFET 41 and the monitor MOSFET 41a are measured.

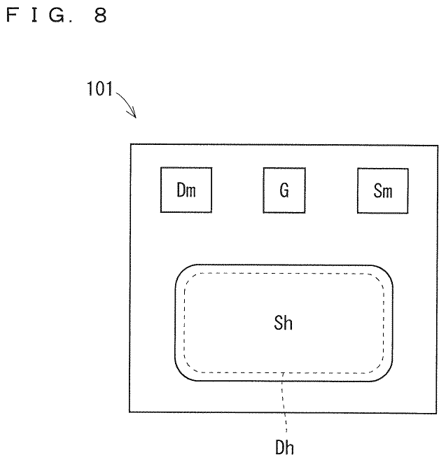

FIG. 8 is a plan view illustrating a configuration of a semiconductor chip which is the semiconductor device according to Embodiment 1. In FIG. 8, a semiconductor chip 101 includes the high voltage MOSFET 41 and the monitor MOSFET 41a illustrated in FIG. 2, etc. The semiconductor chip 101 is provided with a plurality of bonding pads. The bonding pads of the semiconductor chip 101 include a monitor drain pad Dm, a monitor source pad Sm, a gate pad G, and a source pad Sh provided on the front surface of the semiconductor chip 101, and a drain pad Dh provided on the back surface of the semiconductor chip 101.

The monitor drain pad Dm corresponds to the drain electrode 12a and a drain terminal of the monitor MOSFET 41a. The monitor source pad Sm corresponds to the source electrode 11a and a source terminal of the monitor MOSFET 41a. The gate pad G corresponds to the gate electrode 8a and a gate terminal of the monitor MOSFET 41a and the gate electrode 8 and a gate terminal of the high voltage MOSFET 41. The source pad Sh corresponds to the source electrode 11 and a source terminal of the high voltage MOSFET 41. The drain pad Dh corresponds to the drain electrode 12 and a drain terminal of the high voltage MOSFET 41.

When a high voltage is not expected to be applied to the monitor drain pad Dm of the monitor MOSFET 41a, the monitor drain pad Dm is preferably provided within the termination region 30 of the semiconductor chip 101 in plan view. Also, each pad preferably has a size that enables wire bonding. In particular, each of the drain pad Dh of the high voltage MOSFET 41 and the monitor drain pad Dm of the monitor MOSFET 41a is preferably wire-bonded.

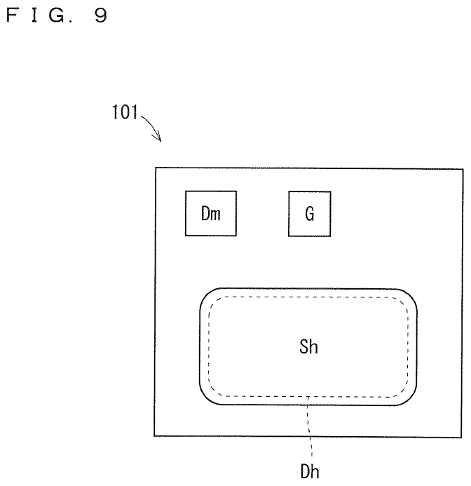

In addition, in the configuration in which the source electrode 11 of the high voltage MOSFET 41 and the source electrode 11a of the monitor MOSFET 41a are electrically connected as illustrated in FIG. 3, a configuration may be adoptable where the monitor source pad Sm as illustrated in FIG. 9 is not provided, by substituting the source pad Sh for the monitor source pad Sm. According to such a configuration, the region of the monitor source pad Sm can be omitted, so that the chip area can be reduced.

When measuring the electrical characteristics of the high voltage MOSFET 41, probes for measurement are brought into contact with the gate pad G and source pad Sh on the front surface of the semiconductor substrate 1, whereas an energizable stage is brought into contact with the drain pad Dh on the back surface of the semiconductor substrate 1, to electrically connect a measuring device and the high voltage MOSFET 41 to each other. The measuring device measures electrical characteristics of the high voltage MOSFET 41 with the monitor source pad Sm and the monitor drain pad Dm being left floating.

When measuring the electrical characteristics of the monitor MOSFET 41a, the probes for measurement are brought into contact with the gate pad G, the monitor source pad Sm, and the monitor drain pad Dm on the surface of the semiconductor substrate 1 to electrically connect the measuring device and the monitor MOSFET 41a to each other. The measuring device measures electrical characteristics of the monitor MOSFET 41a with the drain pad Dh and the source pad Sh being left floating. In the configuration of FIG. 9 in which the monitor source pad Sm is not provided, despite the probe being brought into contact with the source pad Sh, the electrical characteristics of the monitor MOSFET 41a can be measured without any problem by the drain pad Dh being made floating.

Note that the monitor MOSFET 41a may be provided below the monitor drain pad Dm, or may be provided below the monitor source pad Sm.

The measuring device for electrical characteristics applies a voltage to each pad to measure the current between the pads, thereby selectively measuring the electrical characteristics of the high voltage MOSFET 41 and the electrical characteristics of the monitor MOSFET 41a. From these measurements, the threshold voltage of the high voltage MOSFET 41 and the threshold voltage of the monitor MOSFET 41a are obtained. For example, when measuring a MOSFET with a threshold voltage of about 3V, the drain voltage is set to 10 V, the source voltage is set to 0V, and the gate voltage is changed from −10V to +20V and then changed from +20V to −10V. Then, the gate voltage at which the drain current becomes 1 ρA/cm² when the gate voltage changes from +20V to −10V is obtained as the threshold voltage. It should be noted that the drain current that serves as a reference for the threshold voltage is not limited to 1 μA/cm² and may be, for example, 1 mA/cm².

In the method of manufacturing the semiconductor device according to Embodiment 1 described above, the gate electrode 8 and the gate insulating film 7 of the high voltage MOSFET 41 are formed in the same Steps as the gate electrode 8a and the gate insulating film 7a of the monitor MOSFET 41a, respectively. Therefore, the threshold voltage of the high voltage MOSFET 41 and the threshold voltage of the monitor MOSFET 41a obtained in Step S2 are the same or substantially the same.

In the above description, it is assumed that the threshold voltage of the high voltage MOSFET 41 is measured; however measurement thereof may not be necessary. For example, assuming that the threshold voltage of the high voltage MOSFET 41 is the same as the threshold voltage of the monitor MOSFET 41a, the threshold voltage of the monitor MOSFET 41a is measured as the threshold voltage of the high voltage MOSFET 41 without measuring the threshold voltage of the high voltage MOSFET 41.

At Step S3 in FIG. 7, a high gate voltage is applied to the monitor MOSFET 41a. For example, the high gate voltage is a voltage from 30V to 50V, and the application time is from 1 second to 10 hours.

Similarly to Step S2, in Step S4, the threshold voltage of the monitor MOSFET 41a after Step S3 in which the high gate voltage has been applied is obtained by measuring the electrical characteristics of the monitor MOSFET 41a.

That is, in Steps S2 to S4, a high gate voltage, which is a gate voltage equal to or higher than a predetermined voltage, is applied to the monitor MOSFET 41a without applying it to the high voltage MOSFET 41, thereby, obtaining a first electrical characteristic of the monitor MOSFET 41a before application of the high gate voltage and a second electrical characteristic of the monitor MOSFET 41a after application of the high gate voltage. The first electrical characteristic and the second electrical characteristic are obtained for each element, that is, for each semiconductor chip.

At Step S5, the semiconductor wafer is cut into individual elements.

In Step S6, based on the first electrical characteristic and the second electrical characteristic, semiconductor devices that satisfy the predetermined standard are selected. In Embodiment 1, the semiconductor devices that are selected as those that satisfy the predetermined standard are elements in which the difference between the threshold voltage as the first electrical characteristic obtained in Step S2 and the threshold voltage as the second electrical characteristic obtained in Step S4 is equal to or less than the predetermined threshold. That is, elements whose threshold voltage in step S2 and threshold voltage in step S4 are close to each other are selected as elements to be incorporated into a circuit.

At Step S7, the manufacturing process of FIG. 7 is completed by assembling the power module including the elements selected at Step S6.

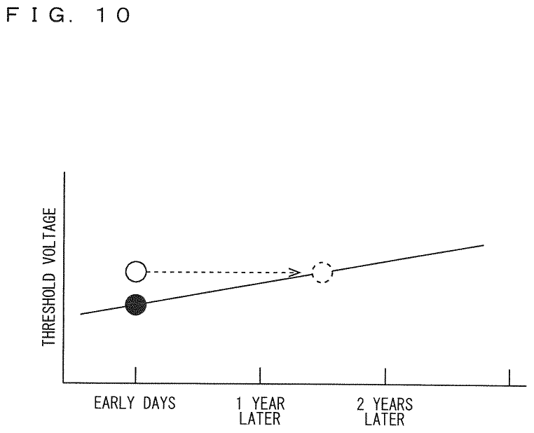

FIG. 10 is a graph illustrating measurement results of the threshold voltage of the high voltage MOSFET 41 and the threshold voltage of the monitor MOSFET 41a. A solid circle represents the threshold voltage of the high voltage MOSFET 41 and the threshold voltage of the monitor MOSFET 41a measured in Step S2. As described above, the threshold voltage of the high voltage MOSFET 41 is the same as the threshold voltage of the monitor MOSFET 41a. An open circle represents the threshold voltage of the monitor MOSFET 41a measured in Step S4.

The threshold voltage of the monitor MOSFET 41a measured in Step S4 is higher than the threshold voltage measured in Step S2. The conceivable cause of the threshold voltage increase is that the high gate voltage stress has been applied to the element in Step S3 that may have induced electron traps that are formed in the gate insulating film 7a in the vicinity of the interface of the semiconductor layer 2 of the monitor MOSFET 41a, leading to the gate insulating film 7a being charged to a negative voltage. Therefore, due to the application of a high gate voltage stress as described above, a stress equivalent to the gate voltage stress applied when operating in the market for a certain period of time (for example, 1.5 years) as indicated by the dotted circle in FIG. 10 can be applied to the monitor MOSFET 41a.

Here, the change in the threshold voltage due to the gate voltage stress of the high voltage MOSFET 41 is considered to be substantially the same as the change of the threshold voltage due to the gate voltage stress of the monitor MOSFET 41a. Therefore, the threshold voltage of the high voltage MOSFET 41 during market operation after shipment can be predicted before shipment of the product.

As described above, in Step S6, elements whose threshold voltages before and after the application of the high gate voltage stress are similar to each other are selected. Therefore, in Step S7, by assembling the power module from the elements selected in Step S6, variations in the electrical characteristics of the individual elements due to operation in the market after shipment can be suppressed, making circuit operation after shipping stabilized. However, a high gate voltage is applied to the monitor MOSFET 41a in Step S3; therefore, the threshold voltage of the monitor MOSFET 41a is higher than the threshold voltage of the high voltage MOSFET 41 up until the time of shipment.

Next, power module assembly in Step S7 will be described. In assembling the power module, a circuit is constructed that incorporates a plurality of chips.

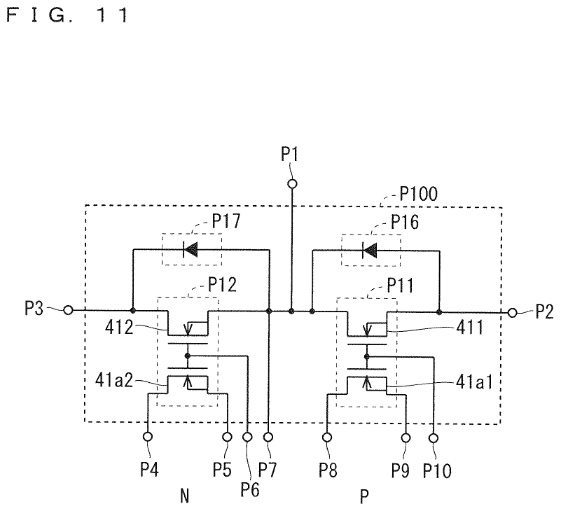

FIG. 11 is a circuit diagram illustrating an example of a half bridge circuit P100 constructed by mounting a plurality of chips. In the circuit of FIG. 11, one SiC-MOSFET element, which is a semiconductor device, is mounted on each of the P-side and the N-side.

A SiC-MOSFET element P11 including a monitor MOSFET 41al and a high voltage MOSFET 411, and a SiC diode P16 are provided on the P side. A SiC-MOSFET element P12 including a monitor MOSFET 41a2 and a high voltage MOSFET 412, and a SiC diode P17 are provided on the N side.

The half bridge circuit P100 has an output terminal P1, a drain terminal P2 of the high voltage MOSFET 411 on the P side, and a source terminal P3 of the high voltage MOSFET 412 on the N side. The half-bridge circuit P100 includes a source terminal P4 of the monitor MOSFET 41a2 on the N side, a drain terminal P5 of the monitor MOSFET 41a2 on the N side, a gate terminal P6 of the monitor MOSFET 41a2 on the N side and the high voltage MOSFET 412 on the N side, and a drain/source terminal P7 which is the drain terminal of the high voltage MOSFET 412 on the N side and the source terminal of the high voltage MOSFET 411 on the P side. The half bridge circuit P100 also includes a source terminal P8 of the monitor MOSFET 41al on the P side, a drain terminal P9 of the monitor MOSFET 41al on the P side, and a gate terminal P10 of the monitor MOSFET 41al on the P side and the high voltage MOSFET 411 on the P side.

The monitor MOSFETs 41al and 41a2 are mounted on the SiC-MOSFET elements P11 and P12 on the P side and N side, respectively, and the threshold voltages of the monitor MOSFETs 41a1 and 41a2 are obtained in Steps S2 and S4.

Specifically, when obtaining the electrical characteristics of the monitor MOSFET 41al on the P side, voltage is applied to the source terminal P8, the drain terminal P9, and the gate terminal P10. It should be noted that when obtaining the electrical characteristics of the high voltage MOSFET 411 on the P side, voltage is applied to the output terminal P1, the drain terminal P2, and the gate terminal P10.

When obtaining the electrical characteristics of the monitor MOSFET 41a2 on the N side, voltage is applied to the source terminal P4, the drain terminal P5, and the gate terminal P6. It should be noted that when obtaining the electrical characteristics of the high voltage MOSFET 412 on the N side, voltage is applied to the output terminal P1, the source terminal P3, and the drain/source terminal P7.

When constructing an inverter, the drain/source terminal P7 of the high voltage MOSFET 411 on the P side and the source terminal P8 of the monitor MOSFET 41al on the P side are shorted together and electrically connected to each other. The drain terminal P2 of the high voltage MOSFET 411 on the P side and the drain terminal P9 of the monitor MOSFET 41al on the P side may be shorted together, or the drain terminal P9 of the monitor MOSFET 41al on the P side may be left floating. However, in the configuration in which the drain terminal P2 and the drain terminal P9 are shorted together, the short is disconnected when obtaining the electrical characteristics of the monitor MOSFET 41al on the P side.

Similarly, when constructing an inverter, the source terminal P3 of the high voltage MOSFET 412 on the N side and the source terminal P4 of the monitor MOSFET 41a2 on the N side are shorted together and electrically connected to each other. The drain/source terminal P7 of the high voltage MOSFET 412 on the N side and the drain terminal P5 of the monitor MOSFET 41a2 on the N side may be shorted together, or the drain terminal P5 of the monitor MOSFET 41a2 on the N side may be left floating. However, in the configuration in which the drain/source terminal P7 and the drain terminal P5 are shorted together, the short is disconnected when obtaining the electrical characteristics of the monitor MOSFET 41a2 on the N side.

In a configuration in which the source terminal of the monitor MOSFET 41a is also used as the source terminal of the high voltage MOSFET 41 as illustrated in FIG. 3, the source terminal P4 on the N side and the source terminal P3 may be the same terminal, and the drain/source terminal P7 on the P side and the source terminal P8 may be the same terminal.

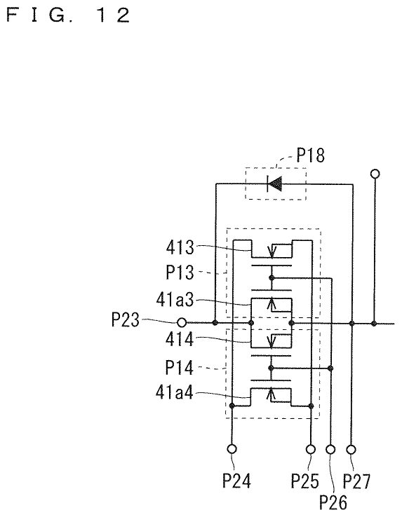

FIG. 12 is a circuit diagram illustrating an example of a half bridge circuit constructed by mounting a plurality of parallel elements. FIG. 12 illustrates the N-side circuit in which includes a SiC-MOSFET element P13 including a monitor MOSFET 41a3 and a high voltage MOSFET 413, a SiC-MOSFET element P14 including a monitor MOSFET 41a4 and a high voltage MOSFET 414, and a SiC diode P18 are provided. That is, the N-side circuit includes two SiC-MOSFET elements and one SiC diode.

The number of terminals of the power module is the same as that of the inverter described above, and when obtaining the electrical characteristics of the high voltage MOSFETs 413 and 414 on the N side, voltage is applied to an output terminal P27, a source terminal P23, and a gate terminal P26. When obtaining the electrical characteristics of the monitor MOSFETs 41a3 and 41a4 on the N side, voltage is applied to a source terminal P24, a drain terminal P25, and a gate terminal P26. In the configuration of FIG. 12, the SiC-MOSFET elements P13 and P14 are connected in parallel; therefore, the electrical characteristics of each element cannot be measured individually. Therefore, to enable individual measurement of the electrical characteristics of each element, the terminals for the monitor MOSFET 41a3 and 41a4 may be separately provided.

<Method of Replacing Semiconductor Device>

Next, a method of replacing a power module including a semiconductor device will be described. First, the threshold voltages of the P-side and N-side high voltage MOSFETs 41 and the monitor MOSFETs 41a are measured before actual operation of the module (for example, before shipment). After the actual operation (for example, after shipment), the threshold voltages of the P-side and N-side high voltage MOSFETs 41 and the monitor MOSFETs 41a are measured using the drain/source terminal P7 every certain period of time (for example, every year or every three years) passes under actual non-operational condition. The certain period does not necessarily have to be exactly the same value. For example, there may be allowance of some time like±one month difference when one year is set. In a country where there is a vehicle inspection system like Japan, when a power module is applied to an automobile, the threshold voltage may be measured at the timing of vehicle inspection, for example. In this manner, the threshold voltages of the high voltage MOSFETs 41 and the monitor MOSFETs 41a are measured at different points of time (that is, at multiple points of time).

The threshold voltages are measured at a certain period, and plotted with time on the horizontal axis and threshold voltage on the vertical axis as illustrated in FIG. 10. When it is predicted that the threshold voltages of the high voltage MOSFETs 41 exceed a predetermined threshold after the next certain period, the entire module will be replaced. In other words, the semiconductor device is replaced when it is determined, based on the threshold voltages of the high voltage MOSFETs 41 and the monitor MOSFETs 41a measured at different points of time, that the threshold voltages of the high voltage MOSFETs 41 after a predetermined period exceed a predetermined threshold.

By employing such a method of replacing a module (or in other words, an operation method), even if the fluctuation amount of the threshold voltages is different for each semiconductor chip, the replacement can be performed to ensure that the threshold voltages of the high voltage MOSFETs 41 do not exceed the predetermined threshold. Therefore, the reliability of the module can be enhanced.

<Summary of Embodiment 1>

The semiconductor device according to Embodiment 1 includes the high voltage MOSFET 41 and the monitor MOSFET 41a provided on the same semiconductor base. According to such a configuration, based on the monitor MOSFET 41a, prediction of fluctuation of the electrical characteristics of the high voltage MOSFET 41 when operated in the market can be performed, thus enabling stabilization of the operation of the circuit including the high voltage MOSFET 41. Consequently, contribution is made to reducing the break down rate of the high voltage MOSFET 41 operating in the market and improving system maintainability. In particular, when the semiconductor base is made of silicon carbide, the threshold voltage tends to fluctuate greatly; therefore, the above stabilization is effective. It should be noted that a high gate voltage is applied to the monitor MOSFET 41a in Step S3; therefore, the threshold voltage of the monitor MOSFET 41a is higher than the threshold voltage of the high voltage MOSFET 41 up until the time of shipment.

Also, the gate electrode 8 of the high voltage MOSFET 41 and the gate electrode 8a of the monitor MOSFET 41a are electrically connected, and the source electrode 11 of the high voltage MOSFET 41 and the source electrode 11a of the monitor MOSFET 41a are electrically connected. According to such a configuration, for example, the positional changes of the probes can be minimized, making the measurement of the electrical characteristics facilitated to perform.

### Embodiment 2

<Cross-Sectional Configuration>

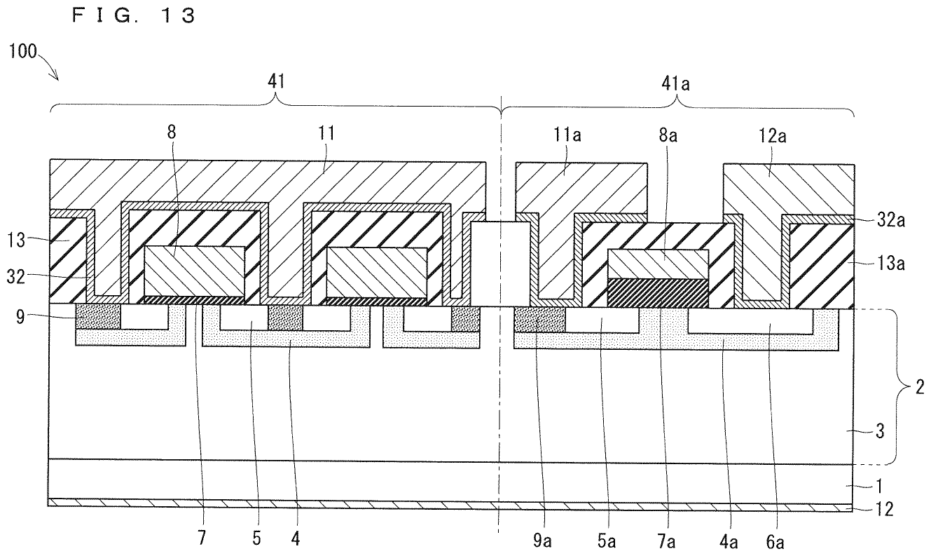

FIG. 13 is a cross-sectional view illustrating a configuration of a semiconductor device 100 according to Embodiment 2 and corresponds to the cross-sectional view of FIG. 2.

As illustrated in FIG. 2, in Embodiment 1, the gate insulating film 7 of the high voltage MOSFET 41 and the gate insulating film 7a of the monitor MOSFET 41a have the same material and the same thickness. Whereas, in Embodiment 2, as illustrated in FIG. 13, the gate insulating film 7a of the monitor MOSFET 41a is thicker than the gate insulating film 7 of the high voltage MOSFET 41. As described below, according to such a configuration, monitoring the fluctuation in the electrical characteristics of the monitor MOSFET 41a can be sensitively performed; therefore, highly accurate prediction of the fluctuation in the electrical characteristics of the high voltage MOSFET 41 when operated in the market can be performed. The configuration of the semiconductor device 100 according to Embodiment 2 is the same as the configuration of the semiconductor device 100 according to Embodiment 1 except that the thicknesses of the gate insulating films 7 and 7a are different.

<Method of Manufacturing Semiconductor Device>

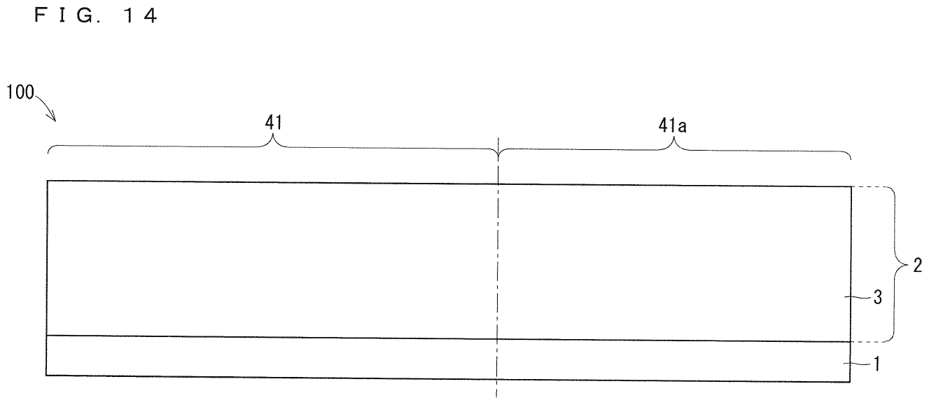

Next, a method of manufacturing the semiconductor device according to Embodiment 2 will be described with reference to FIGS. 14 to 17.

As illustrated in FIG. 14, an n-type low-resistance semiconductor substrate 1 is prepared, and a semiconductor layer 2 including an n-type drift layer 3 is formed on the semiconductor substrate 1 by epitaxial growth. The semiconductor substrate 1 in the example of FIG. 14 is a portion of a semiconductor wafer, and the semiconductor wafer extends in the in-plane direction of the semiconductor substrate 1 in FIG. 14. The n-type impurity concentration of the drift layer 3 is, for example, about 1×10¹³ cm⁻³ to 1×10¹⁸ cm⁻³ and the thickness thereof is, for example, 4 μm to 200 μm.

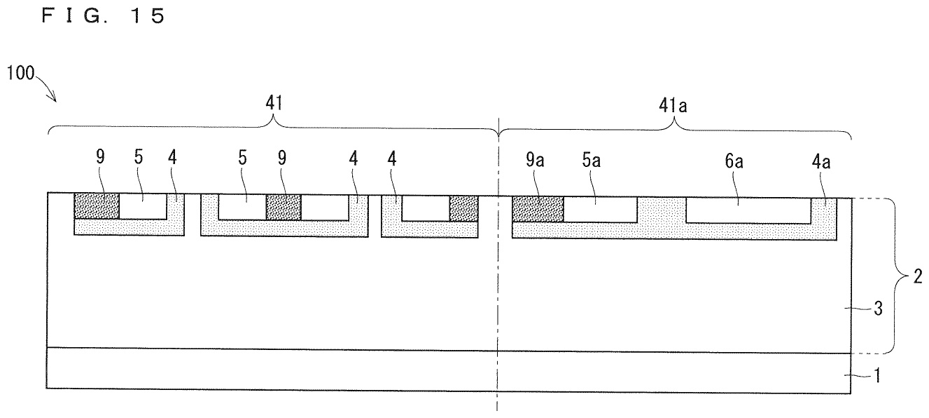

As illustrated in FIG. 15, the p-type well regions 4 and 4a which are apart from each other are selectively formed on drift layer 3. In addition, an n-type source region 5 and a p-type well contact region 9 adjacent to each other are selectively formed on the well region 4, and an n-type source region 5a and a p-type well contact region 9a adjacent to each other and an n-type drain region 6a separated therefrom are selectively formed on the well region 4a. For example, the p-type region is formed by implanting Al ions and the n-type region is formed by implanting N ions using, a resist, an oxide film or the like processed by photolithography as a mask.

The p-type impurity concentration of the well region 4 is, for example, about 1×10¹⁵ cm⁻³ to 1×10¹⁸ cm⁻³ and the well region 4 is formed to have a depth of, for example, 0.3 μm to 2.0 μm from the upper surface of the semiconductor substrate 1. The n-type impurity concentration of the source region 5 is, for example, about 1×10¹⁷ cm⁻³ to 1×10²¹ cm⁻³, which is higher than that of the well region 4, and the bottom surface of the source region 5 is formed so as not to be located below the bottom surface of the well region 4. The well contact region 9 is formed to have the impurity concentration higher than that of well region 4.

Next, annealing is performed in an inert gas atmosphere such as argon gas using a heat treatment apparatus. Annealing is performed, for example, at a temperature of 1300° C. to 1900° C. for about 30 seconds to 1 hour. This annealing activates the ion-implanted n-type impurities such as N and the p-type impurities such as Al.

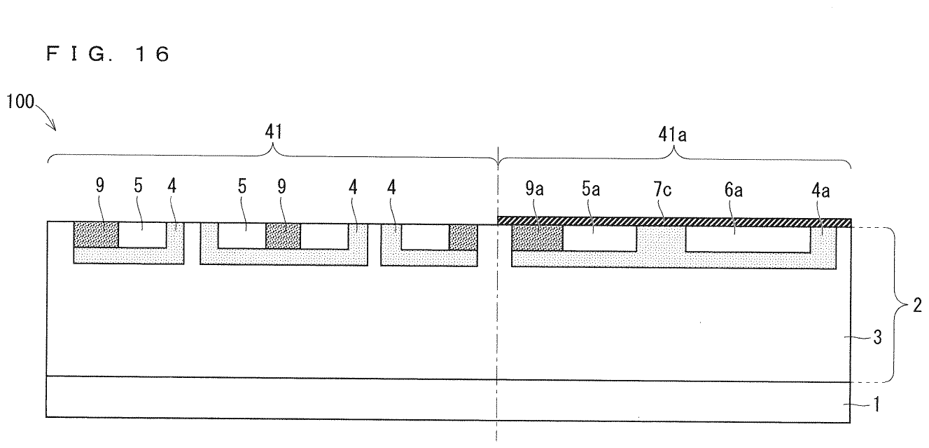

Next, as illustrated in FIG. 16, an insulating film 7c is formed. The insulating film 7c is formed by dry thermal oxidation at 1150° C. or higher, or by a deposition method, for example. After that, a resist is formed so as to cover the region of the monitor MOSFET 41a, and the insulating film 7c in the region not covered with the resist is removed using the resist as a mask. Wet etching using hydrofluoric acid may be used to remove the insulating film 7c, or dry etching may be used.

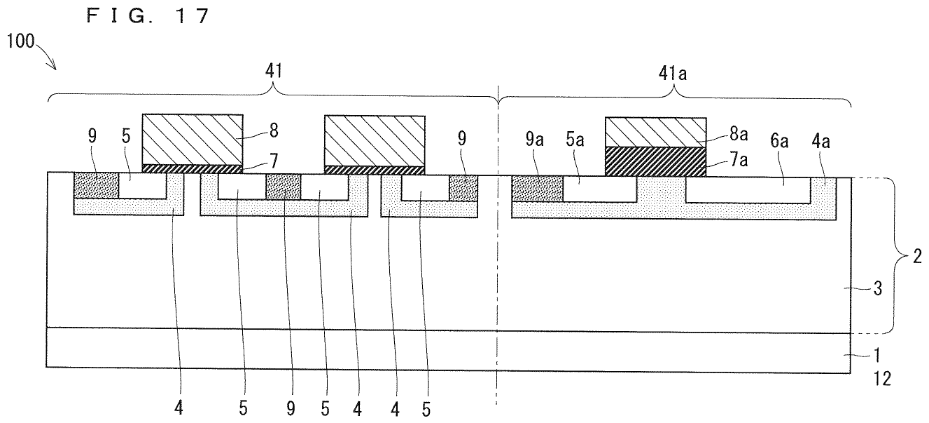

After removing the resist, a similar dry thermal oxidation method or a deposition method and formation of a mask are performed to selectively form an insulating film in the region of the high voltage MOSFET 41 and the region of the monitor MOSFET 41a. By forming an insulating film on the previously formed insulating film 7c, the gate insulating film 7a of the monitor MOSFET 41a thicker than the gate insulating film 7 of the high voltage MOSFET 41 is formed as illustrated in FIG. 17. Heat treatment may be performed in a nitrogen or ammonia atmosphere after the gate insulating films 7 and 7a are formed. Further, the front surface of the drift layer 3 may be annealed at a high temperature in a hydrogen atmosphere before the gate insulating films 7 and 7a are formed.

The gate insulating film 7a of the monitor MOSFET 41a is preferably thicker than the gate insulating film 7 of the high voltage MOSFET 41, and the film thickness ratio of the gate insulating film 7a to the gate insulating film 7 is, for example, 120% or more and 250% or less. If the forming methods of the first-formed insulating film 7c and the later-formed insulating film are set under the same conditions, the above film thickness ratio will be about 200%, which is optimal from the perspective of manufacturing management and throughput.

Next, gate electrodes 8 and 8a are formed. For example, the gate electrodes 8 and 8a are formed by depositing polysilicon by a CVD method and performing etching using a resist processed by photolithography as a mask. Polysilicon may contain impurities such as phosphorus (P) and boron (B). By containing impurities in polysilicon, the sheet resistance of the gate electrodes 8 and 8a can be reduced.

Finally, interlayer insulating films 13 and 13a having contact holes are formed, and then source electrodes 11 and 11a and drain electrodes 12 and 12a are formed, thereby completing the high voltage MOSFET 41 and the monitor MOSFET 41a illustrated in FIG. 13. The materials and forming methods of the gate electrodes 8 and 8a, the source electrodes 11 and 11a, and the drain electrode 12 may be the same as those of the gate electrodes 8 and 8a, the source electrodes 11 and 11a, and the drain electrode 12 described in Embodiment 1.

<Summary of Embodiment 2>

In Embodiment 2, the high voltage MOSFET 41 and the monitor MOSFET 41a have the same well regions 4 and 4a, whereas the gate insulating film 7a is thicker than the gate insulating film 7. Here, the threshold voltage Vth of each of the high voltage MOSFET 41 and the monitor MOSFET 41a is expressed by the following expression (1) through analysis.

Vth=V_{FB}+2Φ_{F}+Q_{B}/Cox+Qss/Cox (1)

wherein V_{FB} represents the flat band voltage, Φ_{F} represents the surface potential, Q_{B} represents the depletion charge, Cox represents the capacitance of the gate insulating film, and Qss represents the charge of the gate insulating film. The capacitance Cox of the gate insulating film is expressed by the following expression (2) through analysis.

Cox=εox/tox (2)

wherein εox represents the dielectric constant of the gate insulating film, and tox represents the film thickness of the gate insulating film.

According to the above expressions (1) and (2), when a constant charge Qss is accumulated at the insulating film interface due to stress of the market operation, an increase in the film thickness tox of the gate insulating film increases the fluctuation of the threshold voltage caused by the charge Qss. Therefore, according to Embodiment 2 in which the gate insulating film 7a of the monitor MOSFET 41a is made relatively thick, fluctuations in the electrical characteristics of the high voltage MOSFET 41 when operated in the market can be accurately predicted.

Embodiments and Modifications can be combined, and Embodiments and Modifications can be appropriately modified or omitted.

The foregoing description is, in all aspects, illustrative and not restrictive, and not limitative. It is therefore understood that numerous modification examples can be devised.

### EXPLANATION OF REFERENCE SIGNS

1 semiconductor substrate, 2 semiconductor layer, 7, 7a gate insulating film, 8, 8a gate electrode, 11, 11a source electrode, 12, 12a drain electrode, 41 high voltage MOSFET, 41a monitor MOSFET, Dh drain pad, Dm monitor drain pad.

1. A semiconductor device comprising
a vertical semiconductor transistor and a horizontal semiconductor transistor provided on a same semiconductor base, wherein
a gate electrode of the vertical semiconductor transistor and a gate electrode of the horizontal semiconductor transistor are electrically connected,
a source electrode of the vertical semiconductor transistor and a source electrode of the horizontal semiconductor transistor are electrically connected,
a drain electrode of the vertical semiconductor transistor and a drain electrode of the horizontal semiconductor transistor are provided on opposite sides with respect to the semiconductor base,
a threshold voltage of the horizontal semiconductor transistor is higher than a threshold voltage of the vertical semiconductor transistor, and
the drain electrode of the horizontal semiconductor transistor is an electrode connected to an electric power supply applying a voltage to the horizontal semiconductor transistor.

2. The semiconductor device according to claim 1, wherein
the semiconductor base includes a wide bandgap semiconductor, and
each of the vertical semiconductor transistor and the horizontal semiconductor transistor includes a MOSFET.

3. The semiconductor device according to claim 1, wherein
a gate insulating film of the vertical semiconductor transistor and a gate insulating film of the horizontal semiconductor transistor have a same material and a same thickness.

4. The semiconductor device according to claim 1, wherein
each of a drain pad corresponding to the drain electrode of the vertical semiconductor transistor and a drain pad corresponding to the drain electrode of the horizontal semiconductor transistor is wire-bonded.

5. The semiconductor device according to claim 1, wherein
a gate insulating film of the horizontal semiconductor transistor is thicker than a gate insulating film of the vertical semiconductor transistor.

6. A method of manufacturing the semiconductor device according to claim 1, wherein
a gate insulating film of the vertical semiconductor transistor and a gate insulating film of the horizontal semiconductor transistor are formed in a same step.

7. A method of manufacturing the semiconductor device according to claim 1, comprising:
obtaining a first electrical characteristic of the horizontal semiconductor transistor before application of the gate voltage and obtaining a second electrical characteristic of the horizontal semiconductor transistor after application of the gate voltage by applying a gate voltage that is a predetermined voltage or higher to the horizontal semiconductor transistor without applying the gate voltage to the vertical semiconductor transistor; and,
selecting semiconductor devices that satisfy a predetermined standard based on the first electrical characteristic and the second electrical characteristic.

8. A method of replacing the semiconductor device according to claim 1, comprising:
measuring threshold voltages of the vertical semiconductor transistor and the horizontal semiconductor transistor at different points of time; and
replacing the semiconductor device when determined, based on the threshold voltages of the vertical semiconductor transistor and the threshold voltages of the horizontal semiconductor transistor measured at different points of time, that the threshold voltages of the vertical semiconductor transistor after a predetermined period exceed a predetermined threshold.
